(19) United States
(12) Patent Application Publication
(10) Pub. No.: US 2010/0120245 A1
(43) Pub. Date: May 13, 2010

(54) PLASMA AND THERMAL ANNEAL TREATMENT TO IMPROVE OXIDATION RESISTANCE OF METAL-CONTAINING FILMS

(76) Inventors: Agus Sofian Tjandra, San Jose, CA (US); Yoshitaka Yokota, San Jose, CA (US); Christopher S. Olsen, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/267,102

(22) Filed: Nov. 7, 2008

(51) Int. Cl. H01L 21/321

(52) U.S. Cl. 438/660; 257/E21.3

(57) ABSTRACT

Method and apparatus are provided for treatment of a deposited material layer. In one embodiment, a method is provided for processing a substrate including depositing a metal-containing layer using an atomic layer deposition technique, exposing the metal-containing layer to a plasma treatment process at a temperature of less than about 200° C., and exposing the metal-containing layer to a thermal anneal process at a temperature of about 600° C. or greater. The plasma treatment process and/or the thermal anneal process may use a nitrating gas, which may form a passivating surface or layer with the metal-containing layer.

### BACKGROUND OF THE INVENTION

1. Field of the Invention

Embodiments of the present invention relate to a method for manufacturing integrated circuit devices. More particularly, embodiments of the invention relate to a system and process for depositing and treating an atomic layer deposition material layer in a semiconductor device.

2. Description of the Related Art

The electronic device industry and the semiconductor industry continue to strive for larger production yields while increasing the uniformity of layers deposited on substrates having increasingly larger surface areas. These same factors in combination with new materials also provide higher integration of circuits per unit area on the substrate. As circuit integration increases, the need for greater uniformity and process control regarding layer characteristics rises.

Several areas of fabrication that are constantly improving include the formation of metal gate electrodes and the deposition of contact barrier layers. Gate electrodes have often been made with silicon based materials, but more frequently are made with metallic materials, such as tungsten or cobalt. However, the materials used for gate electrodes have lacked accessible or tunable electronic properties by varying the compositions of the contained materials. While tantalum materials have been used as barrier layers, tantalum materials have only been scarcely used for the formation of metal gate electrodes, despite the variety of electronic characteristics available from tantalum materials.

Formation of tantalum-containing barrier layers, such as tantalum, tantalum nitride, and other tantalum materials, in multi-level integrated circuits poses many challenges to process control, particularly with respect to contact formation. Contacts are formed by depositing conductive interconnect material in an opening (e.g., via) on the surface of insulating material disposed between two spaced-apart conductive layers. Copper, tungsten, and aluminum are the most popular conductive interconnect materials, but may diffuse into neighboring layers, such as dielectric layers. The resulting and undesirable presence of these metals causes dielectric layers to become conductive and ultimate device failure. Therefore, barrier materials are used to control metal diffusion into neighboring materials.

Barrier layers formed from sputtered tantalum and reactive sputtered tantalum nitride have demonstrated properties suitable for use to control metal diffusion. Exemplary properties include high conductivity, high thermal stability, and resistance to diffusion of foreign atoms. Physical vapor deposition (PVD) processes are used to deposit tantalum materials as gate electrodes or in features of small size (e.g., about 90 nm wide) and high aspect ratios of about 5:1. However, it is believed that PVD processes may have reached a limit at this size and aspect ratio. Also, the variety of compositions for tantalum materials is very limited when using a PVD process.

Attempts have been made to use traditional tantalum precursors found in chemical vapor deposition (CVD) or atomic layer deposition (ALD) processes to deposit tantalum materials. Multiple CVD and ALD processes are anticipated to be used in the next generation technology of 45 nm wide features having aspect ratios of about 10:1 or greater. Also, ALD processes more easily deposit tantalum materials on features containing undercuts than does PVD processes. Formation of tantalum-containing films from CVD or ALD processes using TaCl₅ as a precursor may require as many as three treatment cycles using various radial based chemistries (e.g., atomic hydrogen or atomic nitrogen) to form tantalum materials. Processes using TaCl₅ may also suffer from chlorine contaminants within the tantalum material. While organometallic tantalum precursors may be used to form tantalum materials containing no chlorine contaminants, the deposited materials may suffer with the undesirable characteristic of a high carbon content.

Therefore, there is a need for a process to deposit tantalum-containing materials, such as tantalum nitride, on a substrate, including as a metal gate electrode with reduced contaminants.

### SUMMARY OF THE INVENTION

Embodiments of the invention generally provide methods for depositing a metal-containing material, such as a tantalum nitride material, onto a substrate, and treating the deposited material. In one embodiment, a method is provided for processing a substrate including depositing a metal-containing layer using an atomic layer deposition technique, exposing the metal-containing layer to a plasma treatment process at a temperature of less than about 200° C., and exposing the metal-containing layer to a thermal anneal process at a temperature of about 600° C. or greater.

In another embodiment, a method is provided for processing a substrate including depositing a metal-containing layer using an atomic layer deposition technique, exposing the metal-containing layer to a plasma treatment process comprising a nitrating gas, forming a passivation layer on the meta-containing layer, and exposing the metal-containing layer to a thermal anneal process.

In another embodiment, a method is provided for forming a structure including positioning a substrate in a processing chamber, and the substrate comprising a silicon substrate surface, depositing a polysilicon layer on a silicon substrate surface, depositing a first metal layer on the polysilicon layer, depositing a tantalum nitride layer on the first metal layer, treating a deposited tantalum nitride layer with a thermal anneal, a plasma, anneal, or both, depositing a second metal layer on the treated tantalum nitride layer, depositing a patterned hard mark layer on the metal layer, selectively etching the second metal layer, the tantalum nitride layer, the first metal layer, and the polysilicon layer to expose vertical portions of the polysilicon layer, and selectively oxidizing the silicon substrate surface and the vertical portions of the polysilicon material.

In another embodiment, a method is provided for forming a structure including positioning a substrate in a processing chamber, and the substrate comprising a silicon substrate surface, depositing a high k dielectric material on a silicon substrate surface, depositing a tantalum nitride layer on high k dielectric material, treating a deposited tantalum nitride layer with a thermal anneal, a plasma, anneal, or both, depositing a polysilicon layer on the treated tantalum nitride layer, depositing a patterned hard mark layer on the polysilicon layer, selectively etching the polysilicon layer, the tantalum nitride layer, the high k dielectric material to expose vertical portions thereof, and selectively oxidizing the silicon substrate surface and the vertical portions of the polysilicon material.

In another embodiment, an apparatus is provided including a transfer chamber, one or more decoupled plasma nitridation process chambers coupled to the transfer chamber, one or more thermal anneal chambers coupled to the transfer chamber, and one or more chemical vapor deposition chambers, an atomic layer deposition chamber, or combinations thereof, coupled to the transfer chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic plan view of an exemplary integrated cluster tool adaptable to perform the processes described herein;

FIG. 2A illustrates a schematic, partial cross section of an exemplary processing chamber for forming a thin barrier layer according to a cyclical deposition technique;

FIG. 2B illustrates a schematic diagram of a plasma chamber according to an embodiment of the present invention;

FIG. 3 illustrates a schematic side view of a process of utilizing an ALD tantalum nitride layer in the formation of metal interconnect structures;

FIG. 4 is a cross-sectional view of a substrate containing a tantalum-containing gate electrode in accordance with one embodiment described herein;

FIG. 5 depicts a cross sectional view of a conventional DRAM device formed according to an embodiment of the invention;

FIG. 6A is a cross-sectional view of a substrate prior to applying a selective oxidation process according to one embodiment of the present invention;

FIG. 6B is a cross-sectional view of a substrate following application of a selective oxidation process according to one embodiment of the present invention;

FIG. 7 is a cross-sectional view of a substrate following application of a selective oxidation process according to another embodiment of the present invention.

### DETAILED DESCRIPTION

Embodiments of the invention generally provide methods for treating a deposited ALD metal-containing layer in the same chamber or processing tool. In particular, embodiments of the invention generally provide methods for depositing a tantalum-containing material, such as a tantalum nitride material, onto a substrate, and treating the deposited material. While the following description is directed to tantalum nitride, the post-deposition processes described herein may be used to treat any metal based material including to, and not limited to, tantalum, tantalum nitride and suicides, tantalum alloys, titanium, titanium nitride and silicides, titanium alloys, tungsten, tungsten nitride and silicides, tungsten alloys, hafnium, hafnium oxide, silicides, nitrides, silicates, niobium, niobium nitride and suicides, niobium alloys copper, or any other materials deposited from a metal precursor, including metal halide and organometallic precursors, by an atomic layer deposition process or a pulsed chemical vapor deposition process.

### Deposition Apparatus

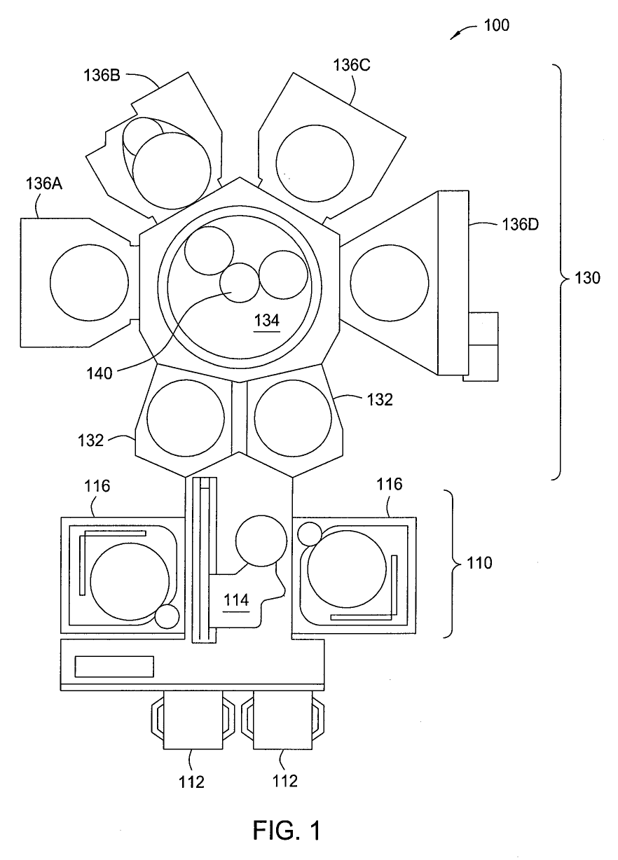

FIG. 1 is a schematic view of an integrated processing system 100 capable of performing the processes disclosed herein. FIG. 1 is a schematic top view of one embodiment of an integrated system 100 capable of performing the processes disclosed herein. The integrated system 100 comprises a cleaning module 110 and a thermal processing/deposition mainframe system 130. As shown in FIG. 1, the cleaning module 110 is an OASIS CLEAN™ system, available from Applied Materials, Inc., located in Santa Clara, Calif. The thermal processing/deposition mainframe system 130 may be a CENTURA® system or an ACT™ mainframe that is commercially available from Applied Materials, Inc., located in Santa Clara, Calif. This particular embodiment of the system to perform the process as disclosed herein is provided to illustrate the invention and should not be used to limit the scope of the invention.

The cleaning module 110 generally includes one or more substrate cassettes 112, one or more transfer robots 114 disposed in a substrate transfer region, and one or more single-substrate clean chambers 116. Other aspects and embodiments of a single-substrate clean system are disclosed in U.S. patent application Ser. No. 09/891,849, entitled “Method and Apparatus for Substrate Cleaning, filed Jun. 25, 2001 and in U.S. patent application Ser. No. 09/891,791, entitled “Substrate Spray Configurations for a Single Substrate Processing Apparatus,” filed Jun. 25, 2001, both of which are herein incorporated by reference in their entirety to the extent not inconsistent with the present disclosure.

The thermal processing/deposition mainframe system 130 generally includes load lock chambers 132, a transfer chamber 134, and processing chambers 136A, 136B, 136C, and 136D. The transfer chamber 134 is preferably between 1 mTorr to about 100 Torr and preferably comprises a non-reactive gas ambient, such as a N₂ ambient. The load lock chambers 132 allow for the transfer of substrates into and out from the thermal processing/deposition mainframe system 130 while the transfer chamber 134 remains under a low pressure non-reactive environment. The transfer chamber includes a robot 140 having one or more blades which transfers the substrates between the load lock chambers 132 and processing chambers 136A, 136B, 136C, and 136D. Any of the processing chambers 136A, 136B, 136C, or 136D may be removed from the thermal processing/deposition mainframe system 130 if not necessary for the particular process to be performed by the system 130.

It is believed that it is advantageous to perform a pre-treatment step on a mainframe system to reduce the formation of native oxides and/or contamination of the pre-treated surface of a substrate prior to layer deposition and/or surface treatments. In other embodiments, the pre-treatment step may include polishing, etching, reduction, oxidation, hydroxylation, annealing and/or baking. It is optional to have the cleaning module 110 coupled with mainframe system 130 as shown in FIG. 1 to further reduce the formation of native oxides over and/or contamination of substrates between cleaning steps and other processing steps. Of course, in other embodiments, cleaning steps may be performed in a cleaning module separate from the thermal processing/deposition mainframe system.

One embodiment of the integrated processing system 100 is configured to form an ALD barrier layer comprises processing chamber 136A adapted to perform the post-deposition plasma treatment process as described above, such as a Decoupled Plasma Nitridation™ (DPN™) process chamber, made by Applied Materials located in Santa Clara, Calif., processing chamber 136B adapted to perform a process such as a chemical vapor deposition chamber or an atomic layer deposition chamber. In another embodiment, processing chamber 136C comprises a rapid thermal processing (RTP) chamber where the structure may be annealed. The RTP chamber may be a XE, XE Plus or Radiance chamber available from Applied Materials, Inc. In another embodiment, processing chamber 136D comprises a second DPN™ process chamber, adapted for the selective oxidation process described herein.

The processing chamber 136A, 136B, 136C, and 136D, allows for multiple processes to be performed on the same tool and within the same portion of the tool without breaking vacuum, i.e., in situ, such as the deposition, the thermal anneal post-deposition, process, and the plasma treatment post-deposition process from the example of a tool and chambers configuration as described previously. Other embodiments of the system 100 are within the scope of the present invention. For example, the position of a particular processing chamber on the system may be altered or the number of processing chamber may be altered.

While the above embodiments are described with respect to FIGS. 1-3, it is recognized that other integrated processing systems and chamber combinations may be used with the embodiments described herein. Furthermore, any number of processing chambers may be part of a non-integrated system.

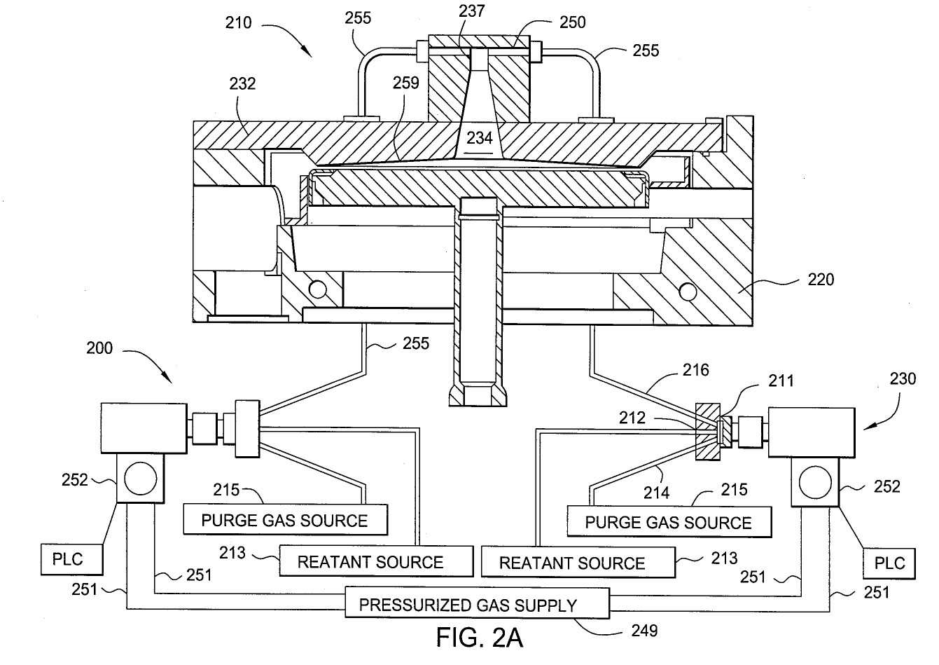

FIG. 2A illustrates a schematic, partial cross section of an exemplary processing chamber for forming a barrier layer according to embodiments of the present invention. Such a processing chamber is available from Applied Materials, Inc. located in Santa Clara, Calif., and a brief description thereof follows. A more detailed description may be found in commonly assigned U.S. patent application Ser. No. 10/032,284, entitled “Gas Delivery Apparatus and Method For Atomic Layer Deposition”, filed on Dec. 21, 2001, which is incorporated herein by reference to the extent not inconsistent with the claimed aspects and disclosure herein. The processing chamber 210 may be integrated into an integrated processing platform shown above, such as an Endura™ platform also available from Applied Materials, Inc.

FIG. 2A is a schematic cross-sectional view of one embodiment of a substrate processing chamber 210 including one or more valve assemblies 200 mounted below a chamber body 220 of the substrate processing chamber 210. The valve assemblies 200 are coupled to gas lines 255 plumbed through the chamber body 220. The gas lines 255 are, in turn, coupled to gas conduits 250 to provide one or more gases into the chamber body 220. The valve assemblies may also be mounted to other substrate processing chambers and may be mounted to other chamber components.

Each valve assembly 200 includes a valve body and a diaphragm assembly 230. The valve body includes a valve chamber 211 in fluid communication with three ports including a reactant inlet 212, a purge inlet 214, and an outlet 216. The reactant inlet 212 is in fluid communication with a reactant source 213 to supply a reactant through the valve chamber 211, through the outlet 216, through the gas line 255, through the gas conduit 250, and into the chamber body 220. The purge inlet 214 is in fluid communication with a purge gas source 215 and is adapted to supply a purge gas through the valve chamber 211, through the outlet 216, through the gas line 255, through the gas conduit 250, and into the chamber body 220. If the substrate processing chamber 210 includes two or more valve assemblies 200, the purge inlet 214 of each valve assembly 200 is preferably coupled to separate purge gas sources 215. In other embodiments, the purge inlet 214 of each valve assembly 200 may be coupled to a common purge gas source.

The gas delivery apparatus 230 includes a chamber lid 232 having an expanding channel 234 formed within a central portion thereof. The chamber lid 232 also includes a bottom surface 259 extending from the expanding channel 234 to a peripheral portion of the chamber lid 232. The bottom surface 259 is sized and shaped to substantially cover the substrate 210 disposed on the substrate support 212. The expanding channel 234 has an inner diameter that gradually increases from an upper portion 237 to a lower portion 235 adjacent the bottom surface 259 of the chamber lid 232. The velocity of a gas flowing therethrough decreases as the gas flows through the expanding channel 234 due to the expansion of the gas. The decreased gas velocity reduces the likelihood of blowing off reactants adsorbed on the surface of the substrate 210.

The gas delivery apparatus 230 also includes at least two high speed actuating valves 252 having one or more ports. At least one valve 252 is dedicated to each reactive compound. For example, a first valve is dedicated to a refractory metal-containing compound, such as tantalum and titanium, and a second valve is dedicated to a nitrogen-containing compound. When a ternary material is desired, a third valve is dedicated to an additional compound. For example, if a silicide is desired, the additional compound may be a silicon-containing compound.

The valves 252 may be any valve capable of precisely and repeatedly delivering short pulses of compounds into the chamber body 220. In some cases, the on/off cycles or pulses of the valves 252 may be as fast as about 100 msec or less. The valves 252 can be directly controlled by a system computer, such as a mainframe for example, or controlled by a chamber/application specific controller, such as a programmable logic computer (PLC) which is described in more detail in the co-pending U.S. patent application Ser. No. 09/800,881, entitled “Valve Control System For ALD Chamber”, filed on Mar. 7, 2001, which is incorporated by reference herein. For example, the valves 242 may be electronically controlled (EC) valves, which are commercially available from Fujikin of Japan as part number FR-21-6.35 UGF—APD.

Referring to FIG. 2A, each of the valves 252 may be an electronically controlled valve, such as a solenoid valve, may be mounted to the diaphragm assembly 230 to selectively provide a pressurized gas from a pressurized gas supply 249, such as air or other gas, coupled to the electronically controlled valve 252 through a gas line 251. Programmable logic controllers (PLC) are coupled to the electronically controlled valves 252 to control electrical signals to the electronically controlled valve 252. The programmable logic controllers are in turn coupled to a main controller which controls the programmable logic controller. Although an electronically controlled valve provides pressurized gas to the diaphragm assembly 230, the valve assembly 200 is a pneumatically actuated valve.

In one embodiment, argon is used as the carrier gas at a flow rate 500 sccm, ammonia enters the chamber at a flow rate of 1500 sccm, and the argon purge flow is at a flow rate 8000 sccm.

FIG. 2B depicts a schematic, cross sectional diagram of a Decoupled Plasma Nitration (DPN) process chamber 260, made by Applied Materials located in Santa Clara, Calif. It is an inductive plasma source chamber that is one example of a chamber that may be used to practice the present invention.

The chamber 260 comprises a process chamber 262 having an electrostatic chuck 268 within a conductive body (wall) 280, and a controller 285. The chamber 262 is supplied with a substantially flat dielectric ceiling 272. Other modifications of the chamber 262 may have other types of ceilings, e.g., a dome-shaped ceiling. Above the ceiling 272 is disposed an antenna comprising at least one inductive coil element 264 (two co-axial elements 264 are shown). The inductive coil element 264 is coupled, through a first matching network 271, to a plasma power source 270. The plasma power source 270 typically is capable of producing up to 3000 W at a tunable frequency in a range from 50 kHz to 13.56 MHz.

The electrostatic chuck 268 includes a first electrode 294 and a second electrode 296 embedded in a dielectric material. The first electrode and second electrode are biased with DC potentials to provide the chucking action that holds the substrate 266. Application of the chucking voltage to the electrostatic chuck 268 and substrate spacing mask produces charge distribution along the underside of the substrate 266 and over the surface of the electrostatic chuck 268. The opposite polarity of these charges produces an attractive electrostatic force between the substrate 266 and the electrostatic chuck 268. This force retains the substrate 266 upon the chuck without relying upon a plasma within the processing chamber to provide a conductive grounding path for the substrate 266. The electrostatic chuck 268 may also be a monopolar chuck.

Details of the monopolar electrostatic chuck are described in U.S. Pat. No. 5,982,607, entitled “Monopolar Electrostatic Chuck Having An Electrode In Contact With A Workpiece,” assigned to Applied Materials, Inc., issued Nov. 9, 1999, and herein incorporated by reference to the extent not inconsistent with the invention. Another example of an electrostatic chuck is described in U.S. Patent No. 5,315,473, entitled “Technique For Improving Chucking Reproducibility,” assigned to Applied Materials, Inc., issued May 24, 1994 and herein incorporated by reference to the extent not inconsistent with the invention.

The electrostatic chuck 268 is coupled, through a second matching network 276, to a biasing power source 274. The biasing power source 274 is generally capable of producing a RF signal having a tunable frequency of 50 kHz to 13.56 MHz and a power of between 0 and 5000 watts. Optionally, the biasing power source 274 may be a DC or pulsed DC source. A controller 285 comprising a central processing unit (CPU) 288, a memory 286, and support circuits 290 for the CPU 288 and facilitates control of the components of the chamber 262 and, as such, of the annealing processes as discussed.

In another embodiment, the voltage for operating the electrostatic chuck 268 can be supplied by a separate “chuck” power supply (not shown). One output terminal of the chucking power supply is connected to the chuck electrode. The other output terminal typically is connected to electrical ground, but alternatively may be connected to a metal body portion of the electrostatic chuck 268. In operation, the substrate is placed in contact with the dielectric material, and a direct current voltage is placed on the electrode to create the electrostatic attractive force or bias to adhere the substrate on the upper surface of the electrostatic chuck 268.

In operation, a semiconductor substrate 266 is placed on the electrostatic chuck 268 and process gases are supplied from a gas panel 284 through entry ports 278 to form a gaseous mixture 295. The gas panel 284 is adapted to provide nitrogen gas, oxygen gas, and hydrogen gas, among others. The nitrogen gas may be used for the plasma processing treatment, and the oxygen and hydrogen gases may be used for the selective oxidation process step described herein. The gaseous mixture 295 is ignited to form a plasma 297 in the chamber 262 by applying power from the plasma source 270. The pressure within the interior of the chamber 262 is controlled using a throttle valve 279 and a vacuum pump 282. Typically, the chamber wall is a conductive body (wall) 280 coupled to an electrical ground 283. The temperature of the conductive body (wall) 280 is controlled using liquid-containing conduits (not shown) that run through the conductive body (wall) 280.

The temperature of the substrate 266 is controlled by stabilizing a temperature of the electrostatic chuck 268. In one embodiment, helium gas from a gas source 292 is provided via a gas conduit 293 to channels (not shown) formed in the surface of the electrostatic chuck 268 to a fine space (not shown) formed between the reverse surface of the substrate 266 and the upper surface of the electrostatic chuck 268. During processing, the electrostatic chuck 268 may be heated by a resistive heater (not shown) within the pedestal of the electrostatic chuck 268 to a steady state temperature and then the helium gas facilitates uniform heating of the substrate 266. Using such thermal control, the substrate 266 is maintained at a temperature between about 50° C. to 350° C.

To facilitate control of the process chamber 262 as described above, the controller 285 may be one of any form of general-purpose, computer processor that can be used in an industrial setting for controlling various chambers and sub-processors. The memory 286, or computer-readable medium, of the CPU 288 may be one or more of readily available memory such as random access memory (RAM), read only memory (ROM), floppy disk, hard disk, or any other form of digital storage, local or remote. The support circuits 290 are coupled to the CPU 288 for supporting the processor in a conventional manner. These circuits include cache, power supplies, clock circuits, input/output circuitry and subsystems, and the like. The inventive method is generally stored in the memory 286 as a software routine. The software routine may also be stored and/or executed by a second CPU (not shown) that is remotely located from the hardware being controlled by the CPU 288.

Other details of the Decoupled Plasma Nitridation process chamber 210 are described in U.S. Patent Application Publication No. 2004/0242021, entitled “Method And Apparatus For Plasma Nitridation Of Gate Dielectrics Using Amplitude Modulated Radio Frequency Energy,” assigned to Applied Materials, Inc., published Dec. 2, 2004 and herein incorporated by reference to the extent not inconsistent with the invention. Examples of suitable DPN chambers include the DPN Centura™, which is commercially available from Applied Materials, Inc., Santa Clara, Calif.

### Tantalum Nitride Deposition

A tantalum nitride layer may be conformally deposited by atomic layer deposition on dielectric material or metal-containing material on a substrate surface or as part of a layering stack to form a device. For example, the tantalum nitride layer may be deposited to a thickness of about 50 Å or less, preferably from about 5 Å to about 20 Å by an atomic layer deposition process on a metal layer, a high k dielectric material, or a polysilicon to act as a barrier layer. One of the advantages of atomic layer deposition over other conventional deposition techniques such as physical vapor deposition and chemical vapor deposition for tantalum nitride is the ability to deposit a conformal layer of tantalum nitride over a surface layer and in the small openings, high aspect ratio, and varied topography of apertures in the formation of interconnect structures. Another of the advantages of the formation of an ALD tantalum nitride layer is the good adhesion of the ALD tantalum nitride over dielectric materials.

Tantalum nitride may be deposited by atomic layer deposition by providing one or more pulses of a tantalum-containing compound at a flow rate from about 100 sccm to about 3,000 sccm for a time period of about 1.0 second or less and one or more pulses of a nitrogen-containing compound at a flow rate from about 100 sccm to about 3,000 sccm for a time period of about 1.0 second or less to a reaction zone having a substrate disposed therein.

Exemplary tantalum-containing compounds include: t-butylimino tris(diethylamino) tantalum (TBTDET); pentakis (ethylmethylamiflo) tantalum (PEMAT); pentakis (dimethylamino) tantalum (PDMAT); pentakis (diethylamino) tantalum (PDEAT); t-butylimino tris(diethyl methylamino) tantalum(TBTMET) t-butylimino tris(dimethyl amino) tantalum (TBTDMT); bis(cyclopentadienyl) tantalum trihydride ((Cp)2TaH3); bis(methylcYcloPentadieflYI) tantalum trihydride ((CpMe)2TaH3); derivatives thereof; and combinations thereof. Preferably, the tantalum-containing compound comprises PDMAT. Exemplary nitrogen-containing compounds include: ammonia; hydrazine; methylhydrazine; dimethylhydrazine; t-butylhydrazine; phenylhydrazine; azoisobutafle ethylazide; derivatives thereof; and combinations thereof. Preferably, the nitrogen-containing compound comprises ammonia.

It is to be understood that these compounds or any other compound not listed above may be a solid, liquid, or gas at room temperature. For example, PDMAT is a solid at room temperature and TBTDET is a liquid at room temperature. Accordingly, the non-gas phase precursors are subjected to a sublimation or vaporization step, which are both well known in the art, prior to introduction into the processing chamber. A carrier gas, such as argon, helium, nitrogen, hydrogen, or a mixture thereof, may also be used to help deliver the compound into the processing chamber, as is commonly known in the art.

The heater temperature of the substrate support is maintained at a low temperature from about 100° C. and 300° C. In one aspect, it is believed that the low deposition temperature helps provide a more conformal tantalum nitride layer.

In a particular embodiment, a tantalum nitride layer having a thickness between 10 and 100 Angstroms, for example, about 80 Angstroms, is formed by atomic layer deposition by cyclically introducing PDMAT and ammonia to the substrate surface. To initiate the deposition of the tantalum nitride layer, a carrier/inert gas is introduced into the processing chamber 600 to stabilize the pressure and temperature therein. The carrier gas such as argon at a flow rate between 6000 to 10000 sccm is allowed to flow continuously during the deposition process such that only the argon flows between pulses of each compound. A first pulse of PDMAT is provided from the gas source 213 at a flow rate from about 400 sccm to about 1000 sccm, with a pulse time of about 2.0 seconds or less after the chamber temperature and pressure have been stabilized at about 200° C. to about 300° C. to about 1 Torr to about 5 Torr. A pulse of ammonia is then provided at a flow rate from about 1000 sccm to about 2000 sccm, with a pulse time of about 2.0 seconds or less.

A pause between pulses of PDMAT and ammonia is about 1.0 second or less, preferably about 0.5 seconds or less, more preferably about 0.1 seconds or less. In various aspects, a reduction in time between pulses at least provides higher throughput. As a result, a pause after the pulse of ammonia is also about 1.0 second or less, about 0.5 seconds or less, or about 0.1 seconds or less. Argon gas flowing from about 1,000 sccm to about 10,000 sccm, such as from about 3,000 sccm to about 6,000 sccm, is continuously provided. In one aspect, a pulse of PDMAT may still be in the chamber when a pulse of ammonia enters. In general, the duration of the carrier gas and pump evacuation should be long enough to prevent the pulses of PDMAT and ammonia from mixing together in the reaction zone.

The heater temperature is maintained from about 100° C. to about 300° C., for example about 275° C., at a chamber pressure from about 1.0 to about 5.0 Torr. Each cycle consisting of a pulse of PDMAT, pause, pulse of ammonia, and pause provides a tantalum nitride layer having a thickness from about 0.3 Å to about 1.0 Å per cycle. The alternating sequence may be repeated until the desired thickness is achieved.

In another tantalum nitride atomic layer deposition process, the nitride layer may be deposited as follows. A tantalum nitride, TaN, barrier layer may be formed by cyclically introducing PDMAT and ammonia to the substrate surface. To initiate the cyclical deposition of the TaN layer, a carrier gas such as argon is introduced into the processing chamber 210 to stabilize the pressure and temperature therein. The carrier gas is allowed to flow continuously during the deposition process such that only the argon flows between pulses of each compound. A first pulse of PDMAT is provided from a gas source at a flow rate between about between about 100 sccm and about 400 sccm, with a pulse time of about 0.6 seconds or less after the chamber temperature and pressure have been stabilized at about 200° C. to about 300° C., and about 1 Torr to about 5 Torr. A pulse of ammonia is then provided from a gas source at a flow rate between about 200 sccm and about 600 sccm, with a pulse time of about 0.6 seconds or less.

A pause between pulses of PDMAT and ammonia is about 1.0 second or less, preferably about 0.5 seconds or less, more preferably about 0.1 seconds or less. In various aspects, a reduction in time between pulses at least provides higher throughput. As a result, a pause after the pulse of ammonia is also about 1.0 second or less, about 0.5 seconds or less, or about 0.1 seconds or less. Argon gas flowing between about 100 sccm and about 1,000 sccm, such as between about 100 sccm and about 400 sccm, is continuously provided from the gas source 240 through each valve 242. In one aspect, a pulse of PDMAT may still be in the chamber when a pulse of ammonia enters. In general, the duration of the carrier gas and/or pump evacuation should be long enough to prevent the pulses of PDMAT and ammonia from mixing together in the reaction zone.

The heater temperature is maintained between about 100° C. and about 300° C., for example about 275° C. at a chamber pressure between about 1.0 and about 5.0 Torr. Each cycle consisting of a pulse of PDMAT, pause, pulse of ammonia, and pause provides a tantalum nitride layer having a thickness between about 0.3 Å and about 1.0 Å per cycle. The alternating sequence may be repeated until the desired thickness is achieved, which may be less than about 20 Å, such as about 10 Å. Accordingly, the deposition method may require between 10 and 70 cycles, and has been observed to be more typically between 20 and 30 cycles for a desired thickness less than about 20 Å, such as about 10 Å.

Exemplary tantalum metal containing compounds include organometallic tantalum containing compounds, for example, t-butylimino-tris(diethylamino)tantalum (TBTDET), pentakis(ethylmethylamino)tantalum (PEMAT), pentakis(dimethylamino)tantalum (PDMAT), pentakis(diethylamino)tantalum (PDEAT), t-butylimino-tris(ethylmethylamino)tantalum (TBTMET), t-butylimino-tris(dimethylamino)tantalum (TBTDMT), bis(cyclopentadienyl)tantalum trihydride ((Cp).sub.2TaH.sub.3), bis(methylcyclopentadienyl)tantalum trihydride ((CpMe).sub.2TaH.sub.3), tantalum hydride (Cp).sub.2TaH.sub.3, tantalum pentafluoride (TaF.sub.5), tantalum pentachloride (TaCl.sub.5), tantalum pentabromide (TaBr.sub.5), tantalum pentaiodide (TaI.sub.5), and combinations thereof.

Exemplary nitrogen containing compounds include activated-dinitrogen, ammonia, hydrazine, methylhydrazine, dimethylhydrazine, t-butylhydrazine, phenylhydrazine, azoisobutane, ethylazide, tert-butylamine, allylamine, derivatives thereof, and combinations thereof. Also, nitrogen containing compounds may be activated with a plasma, for example, a remote plasma nitridation (RPN) process.

Tantalum nitride layer deposited by the process may have a layer composition of tantalum to nitrogen ratio from about 1:1 to about 3:1.

The tantalum nitride deposition process may be performed under the following deposition conditions including supplying the tantalum precursor at a rate between about 1 sccm and about 100 sccm, such as between about 5 sccm and about 50 sccm, supplying the nitrogen containing reductant at a rate between about 1 sccm and about 100 sccm, such as between about 5 sccm and about 50 sccm, supplying a carrier gas at a flow rate between about 100 sccm and about 1,000 sccm, such as between about 100 sccm and about 700 sccm, maintaining the chamber pressure less than about 120 Torr, such as between about 1 Torr and about 50 Torr, for example, between about 1 Torr and about 5 Torr, and maintaining the deposition temperature between about 100° C. and about 400° C., such as between 175° C. and about 350° C., for example 275° C.

The deposited tantalum nitride layer may be deposited by any atomic layer process including process described herein or as described in U.S. Pat. No. 7,211,508, issued on May 1, 2007, which is incorporated by reference to the extent not inconsistent with the disclosure and claim aspects herein. ALD deposition of metal and metal nitride layer are more further described in U.S. patent application Ser. No. 10/281,079, filed on Oct. 25, 2002, which is incorporated by reference to the extent not inconsistent with the claim aspects and disclosure herein.

### Post-Deposition Treatment Options

After the deposition of a metal-containing layer, such as copper, tungsten, or tantalum, including a nitrogen-containing metal-containing layer, such as tantalum nitride layer deposition described herein, the substrate may be treated with a plasma treatment and/or a thermal anneal process. For example, the post-deposition process may include a thermal anneal or a plasma treatment and then a thermal anneal. The plasma treatment process is an optional process. While the following process is described with regard to tantalum nitride, any metal-containing layer, either with or without nitrogen, may be processed using the thermal process and/or plasma treatment described herein.

The plasma treatment may be performed in situ with the atomic layer deposition apparatus if the deposition chamber is adapted for plasma processing. Additionally, the plasma treatment process may be performed in a DPN™ chamber, commercially available from Applied Materials of Santa Clara, Calif. The ALD deposition chamber and the plasma treatment chamber may be disposed on the same tool and the respective processes may be performed within the same tool without breaking vacuum, i.e., in-situ.

A substrate structure having one or more metal-containing layers, such as tantalum-nitride layers or sublayers, is positioned in a process chamber. Plasma treating may be done after formation of each layer of an atomic layer deposition process, or may be done after formation of a plurality of layers from an atomic layer deposition process. For example, plasma treating may take place after approximately every 0.003 to 0.005 microns (30 to 50 Angstroms) of a layer or after formation of approximately every 7 to 10 sublayers. However, plasma treating may be done after formation of a sublayer, which is approximately 0.0001 to 0.0004 microns (1 to 4 Angstroms).

The plasma treatment may be performed by supplying a plasma treatment gas to the processing chamber. The plasma treatment gas includes an inert gas, hydrogen gas, or combinations thereof. Suitable inert gases include noble gases, such as argon (Ar), neon (Ne), xenon (Xe), helium (He), and combinations thereof. It is believed that a thermal anneal and/or plasma treatment provides a passivating surface by densification of an upper surface on a metal-containing layer, either nitrogen-containing or nitrogen-free, for when an inert gas is used as the processing gases for the anneal and/or treatment process.

In a further embodiment, a nitrating gas may be supplied to the processing chamber for the plasma treatment process. A nitrating gas is any nitrogen-containing gas that chemically reacts with a deposited material layer during the plasma treatment and/or thermal anneal process described herein. In some embodiments, a nitrating gas is any gas that can implant nitrogen atoms, nitrogen ions, or nitrogen radicals into a material layer formed on a substrate surface by the plasma treatment and/or thermal anneal process described herein.

The nitrating gas may include nitrogen containing compounds include activated-dinitrogen, ammonia, hydrazine, methylhydrazine, dimethylhydrazine, t-butylhydrazine, phenylhydrazine, azoisobutane, ethylazide, tert-butylamine, allylamine, derivatives thereof, and combinations thereof. In one example, nitrogen gas (N₂) gas from a gas source is introduced into chamber to plasma treatment substrate structure. The plasma treatment utilizing a nitrating gas is believed to form a passivating surface or passivation layer on the material to be treated. In one additional example for copper materials, the plasma treatment with a nitrating gas is believed to remove any oxidizes and provide a passivating surface to prevent oxidation of the copper surface through processing chambers or processing tools.

Additionally, it is believed that a thermal anneal and/or plasma treatment provides a passivating surface by densification of an upper surface for a nitrogen containing metal-containing layer, such as tantalum nitride, when a nitrating gas is used as the processing gases for the anneal and/or treatment process. For example, for tantalum nitride, the plasma treatment with a nitrating gas is believed to form a nitrogen rich tantalum nitride surface with improved oxidation resistance properties.

Further, it is believed that a thermal anneal and/or plasma treatment provides a passivating layer for a nitrogen-free metal-containing layer, such as tantalum, when a nitrating gas is used as the processing gases for the anneal and/or treatment process. In another example for tantalum, the plasma treatment with a nitrating gas is believed to form a nitrogen rich tantalum nitride surface with improved oxidation resistance properties.

The plasma treatment gas may be supplied at a flow rate from about 20 to about 500 standard cubic centimeters per minute (sccm), such as from about 100 sccm to about 500 sccm, for example, about 200 sccm.

Power may then be applied to the processing chamber to generate a plasma. The power application and the plasma generation process may be varied by process chamber type. In one example of the plasma generating process, a processing chamber includes a showerhead and substrate support pedestal provide in part spaced apart electrodes. An electric field may be generated between these electrodes to ignite a process gas introduced into chamber to provide a plasma. A pedestal is coupled to a source of radio frequency (RF) power source through a matching network, or alternatively, a RF power source may be coupled to showerhead and matching network. The matching network may comprise different circuits for one or more RF power sources, and both RF power sources may be coupled to showerhead and pedestal, respectively. The RF power may be applied at a frequency in a range from about 10 MHz to about 30 MHz, for example, about 13.56 MHz.

Alternatively, the chamber and process may be adapted with a dual-frequency RF system to generate the plasma. A dual-frequency source of mixed RF power provides a high frequency power in a range from about 10 MHz to about 30 MHz, for example, about 13.56 MHz, as well as a low frequency power in a range of from about 10 KHz to about 1 MHz, for example, about 350 KHz. When a dual frequency RF system is used, the ratio of the second RF power to the total mixed frequency power is preferably less than about 0.6 to 1.0 (0.6:1). The applied RF power and use of one or more frequencies may be varied based upon the substrate size and the equipment used.

A power level of from about 50 W to about 2500 W, such as from about 500 to about 2100, for example, about 2000 W, may be applied to the processing chamber to generate the plasma. The plasma may be generated from about 1 to about 300 seconds, such as from about 30 to about 90 seconds, for example, about 60 seconds. The substrate temperature may be maintained from about 20° C. to less than about 200° C., such as from about 100° C. to about 150° C., for example, about 100° C., and the chamber pressure may be maintained from about 0.1 milliTorr (mTorr) to about 50 mTorr, such as from about 5 mTorr to about 25 mTorr, for example, about 20 mTorr, during the plasma process.

An example of suitable plasma treatment process that may provide a passivation surface includes supplying nitrogen gas to the processing chamber at a flow rate of about 200, sccm, applying a power level of about 2000 W at a frequency of about 13.56 MHz, for a period of 60 seconds, maintaining a chamber pressure of about 20 milliTorr, and a maintaining a chamber temperature from about 100° C. to about 150° C.

The plasma treating process has been observed to provide an initial to post deposition increase in densification from about 10% to about 25%.

While not wishing to be bound by theory, it is believed that plasma treating reduces the presence of contaminants, such as halides and organic groups, disposed in the deposited layer from the precursors during the ALD deposition process, which in turn reduces resistivity and improved densification of the deposited material. The densified surface of the metal-containing layer may have a depth or thickness up to about 50 Å, such as up to about 20 Å, by the processes described herein. The densified surface may perform as a passivation layer to prevent oxidation reactions or other reactions from occurring with the metal-containing material surface.

Additionally, if a nitrating gas is used for the plasma treatment, it is believed that nitrogen ions or nitrogen radicals will be implanted into the bulk of the deposited metal-containing material, such as within a depth up to about 50 Å, such as up to about 20 Å. It is also believed that plasma treating with the nitrating gas reduces and/or replaces contaminants, such as halides and organic groups, disposed in the deposited layer from the precursors during the ALD deposition process, which in turn reduces resistivity and improved densification of the deposited material. The nitrated surface or layer may perform as a passivation layer to prevent oxidation reactions or other reactions from occurring with the metal-containing material surface.

The thermal anneal treatment may be performed in situ with the atomic layer deposition apparatus and/or plasma treatment process if the deposition chamber is adapted for plasma processing and high temperature annealing. Additionally, the thermal anneal treatment process may be performed in a RTP™ anneal chamber, commercially available from Applied Materials of Santa Clara, Calif. The anneal chamber, the ALD deposition chamber, and the plasma treatment chamber may be disposed on the same tool and the respective processes may be performed within the same tool without breaking vacuum, i.e., in-situ.

The thermal anneal treatment may be performed by supplying an annealing gas. The thermal anneal treatment gas includes an inert gas, hydrogen gas, or combinations thereof. Suitable inert gases include noble gases, such as argon (Ar), neon (Ne), xenon (Xe), helium (He), and combinations thereof.

In a further embodiment, a nitrating gas may be supplied to the processing chamber for the plasma treatment process. The nitrating gas may include nitrogen containing compounds include activated-dinitrogen, ammonia, hydrazine, methylhydrazine, dimethylhydrazine, t-butylhydrazine, phenylhydrazine, azoisobutane, ethylazide, tert-butylamine, allylamine, derivatives thereof, and combinations thereof. In one example, nitrogen gas (N₂) gas from a gas source is introduced into chamber to plasma treatment substrate structure.

The annealing gas may be supplied at a flow rate from about 1000 to about 50000 standard cubic centimeters per minute (sccm), such as from about 5000 sccm to about 20000 sccm, for example, about 10000 sccm. The chamber may then be heated to provide a substrate temperature from about 600° C. to about 1100° C., such as from about 900° C. to about 1000° C., for example, about 950° C. The substrate may be annealing from about 1 to about 300 seconds, such as from about 15 to about 120 seconds, for example, about 30 seconds. The chamber pressure may be maintained from about 1 Torr to about 200 Torr, such as from about 50 Torr to about 100 Torr, for example, about 100 Torr, during the annealing process.

The thermal annealing process has been observed to provide an initial to post deposition increase in densification, as measured by thickness shrinkage, from about 10% to about 25%. For example, the densification has been has been observed to be 10% at about 600° C., 16% at 800° C., and about 23% at 1000° C. The combined plasma and annealing processes has been observed to provide an initial to post deposition increase in densification from about 10% to about 25%. While not being bound by any theory, it is believed that the post-deposition treatment of a deposited ALD layer remove organic materials and other impurities from the deposited materials to improve layer densification and thus, barrier properties.

An example of suitable plasma treatment process including supplying nitrogen gas to the processing chamber at a flow rate of about 10000, sccm, heating the substrate to about 1000° C., for a period of 30 seconds, and maintaining a chamber pressure of about 100 Torr.

It is further believed that a thermal anneal treatment following a plasma treatment using a nitrating gas or a thermal anneal process prevents outgassing of any implanted nitrogen ions or nitrogen radicals. Additionally, it is believed that the combination of plasma treatment and thermal anneal treatment ensures the stability of any passivation performed on the metal-containing material.

Examples of the processes described herein are as follows:

### EXAMPLE 1

Metal Nitride film densification. An atomic layer deposited tantalum nitride layer from an organometallic tantalum precursor and ammonia precursor was observed to have a deposition thickness of 80 Å. The deposited tantalum nitride layer may be deposited by any atomic layer process including process described herein or as described in U.S. Pat. No. 7,211,508, issued on May 1, 2007, which is incorporated by reference to the extent not inconsistent with the disclosure and claim aspects herein.

The deposited ALD tantalum nitride layer was exposed to a thermal anneal at 800° C. and 1000° C. while supplying nitrogen gas to the processing chamber at a flow rate of about 10000, sccm, heating the substrate for a period of 30 seconds, and maintaining a chamber pressure of about 100 Torr. The anneal layer was observed to have a thickness of about 65 Å at 800° C. and a thickness of about 59 Å at 1000° C. The tantalum atomic percentage for the deposited layer was observed to be about 45% at about 75 Å depth. The decreasing thickness was observed to be increasing density of the deposited tantalum nitride layer and an increasing tantalum concentrations. It is believed that increasing the densification of the tantalum nitride layer results in improved oxidation resistance.

### COMPARISON EXAMPLE 1

In a comparison example, deposited tantalum nitride layers as described herein were exposed to the thermal process and/or plasma treatment. It is believed that increased tantalum concentrations in the deposited tantalum nitride layers corresponds to less oxidation and thus, increased oxidation resistance for subsequent processing.

In the first comparison example process, the deposited tantalum nitride layer was not exposed to a post deposition treatment prior to oxidation and was rather exposed to a decoupled plasma oxidation, such as the process described above for selective oxidation with a composition gas of 90 volume percent (vol. %) hydrogen gas (H₂) and 10 vol. % oxygen gas (O₂), and then a thermal anneal process including supplying nitrogen gas to the processing chamber at a flow rate of about 10000, sccm, heating the substrate to about 1000° C., for a period of 30 seconds, and maintaining a chamber pressure of about 100 Torr. The post-annealing tantalum atomic percentage (atomic %) was observed to be about 38% at about 75 Å depth.

In the second comparison example process, the deposited tantalum nitride layer was exposed to a post-deposition thermal anneal process, and then a decoupled plasma oxidation, such as the process described above for selective oxidation with a composition gas of 90 volume percent (vol. %) hydrogen gas (H₂) and 10 vol. % oxygen gas (O₂), and a second thermal anneal process with both thermal anneal processing steps including supplying nitrogen gas to the processing chamber at a flow rate of about 10000 sccm, heating the substrate to about 1000° C., for a period of 30 seconds, and maintaining a chamber pressure of about 100 Torr. The post-annealing tantalum atomic % was observed to be about 42% at about 75 Å depth.

In the third comparison example process, the deposited tantalum nitride layer was exposed to a post-deposition plasma treatment process and a thermal anneal process, and then a decoupled plasma oxidation, such as the process described above for selective oxidation with a composition gas of 90 volume percent (vol. %) hydrogen gas (H₂) and 10 vol. % oxygen gas (O₂), and a second thermal anneal process with both thermal anneal processing including supplying nitrogen gas to the processing chamber at a flow rate of about 10000 sccm, heating the substrate to about 1000° C., for a period of 30 seconds, and maintaining a chamber pressure of about 100 Torr. The plasma treatment process including supplying nitrogen gas to the processing chamber at a flow rate of about 200, sccm, applying a power level of about 2000 W at a frequency of about 13.56 MHz, for a period of 60 seconds, maintaining a chamber pressure of about 20 milliTorr, and a maintaining a chamber temperature from about 100° C. to about 150° C. The post-annealing tantalum atomic % was observed to be about 44% at about 75 Å depth.

### Structures

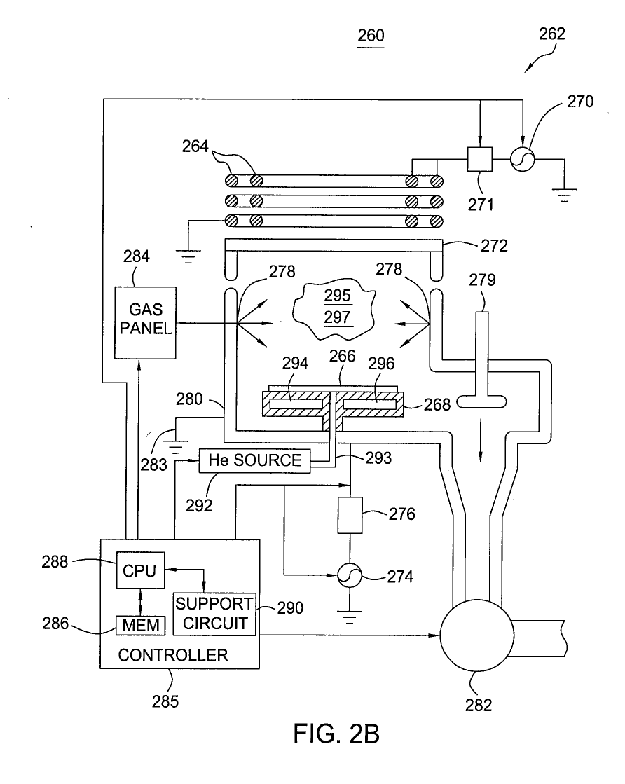

FIG. 3 illustrates one embodiment of a process of utilizing ALD tantalum nitride deposition in the formation of metal interconnect structures. A substrate 312 may be preconditioned to prepare the surface for additional modification. The substrate 312 may comprise a dielectric material and further include conductive materials such as metals or polysilicon, which conductive materials may comprise portions semiconductor structures (not shown) that contact the metal interconnect stack 310.

The preconditioning options include nitrogen plasma, water plasma, hydrogen and helium plasma, low energy plasma, pre-flash with titanium or aluminum, or other precleaning process. A metal interconnect 310 is formed beginning with a dielectric layer 314 being deposited and patterned to expose a substrate surface 318 through the dielectric layer 314. A tantalum nitride layer 320 is deposited by atomic layer deposition over a substrate structure. The tantalum nitride layer 320 is then treated with one or more of the post deposition processes described herein. A passivation surface or layer 321 may be formed within the upper portion of the tantalum nitride layer 320 as described herein using the plasma treatment and/or thermal anneal process.

An optional tantalum layer (not shown) may be deposited by physical vapor deposition over the tantalum nitride. Additionally, an optional titanium flash step may be performed prior to depositing the optional tantalum layer by physical vapor deposition over the resulting substrate structure. A bulk metal layer 324, such as copper or tungsten is then deposited to fill in feature definition 322, which may be performed with the use of an optional seed layer (not shown) deposited on the tantalum nitride layer 320 prior to the bulk metal layer 324 deposition.

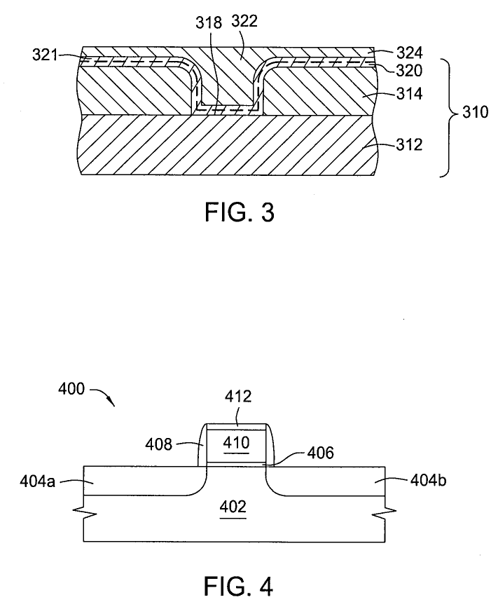

In one embodiment as depicted in FIG. 4, tantalum-containing gate 410 is deposited by methods described herein as a gate electrode on substrate 400. Substrate 400 contains a source layer 404a and a drain layer 404b formed by implanting ions into substrate surface 402. The segments of source/drain layers 404a, 404b are bridged by the tantalum-containing gate 410 formed on gate insulting layer 406 (e.g., hafnium oxide or hafnium silicate). An off-set layer or spacer 408 (e.g., silicon nitride) is deposited on both sides of tantalum-containing gate 410. A metal contact layer 412 (e.g., tantalum or tungsten) is deposited on the tantalum-containing gate 410. Generally, tantalum-containing gate 410 is deposited with a thickness in a range from about 40 Å to about 200 Å. Preferably, tantalum-containing gate 410 is deposited by an ALD process and deposited on a source/drain area of source layer 404a and drain layer 404b on substrate surface 402 to form a gate electrode. The tantalum-containing gate 410 may be treated with one or more of the post-deposition for the plasma treatment and/or thermal anneal process described herein. While not shown a passivation surface or layer may be formed within the upper portion of the tantalum-containing gate 410 as described herein using the plasma treatment and/or thermal anneal process.

The tantalum-containing gate 410 may have a varied composition to better control the work function between source layer 404a and drain layer 404b. Tantalum-containing gate 410 contains tantalum, nitrogen and optionally silicon, boron, phosphorus, carbon and combinations thereof. The work function of tantalum-containing gate 410 may be adjusted to be less resistive by increasing the nitrogen and/or phosphorus concentration relative to the tantalum concentration. In one example, tantalum-containing gate 410 contains tantalum nitride with a nitrogen concentration in a range from about 40 atomic percent (at. %) to about 70 at. %, preferably from about 50 at. % to about 63 at. %. In another example, tantalum-containing gate 410 contains tantalum phosphorous nitride with a phosphorus concentration in a range from about 10 at. % to about 50 at. %, preferably from about 20 at. % to about 30 at. %.

Alternatively, the work function of tantalum-containing gate 410 may be adjusted to be more resistive by increasing the carbon, silicon and/or boron concentration relative to the tantalum concentration. In one example, tantalum-containing gate 410 contains tantalum silicon nitride with a silicon concentration in a range from about 10 at. % to about 20 at. %. In another example, tantalum-containing gate 410 contains tantalum boron nitride with a boron concentration in a range from about 20 at. % to about 60 at. %, preferably from about 30 at. % to about 50 at. %.

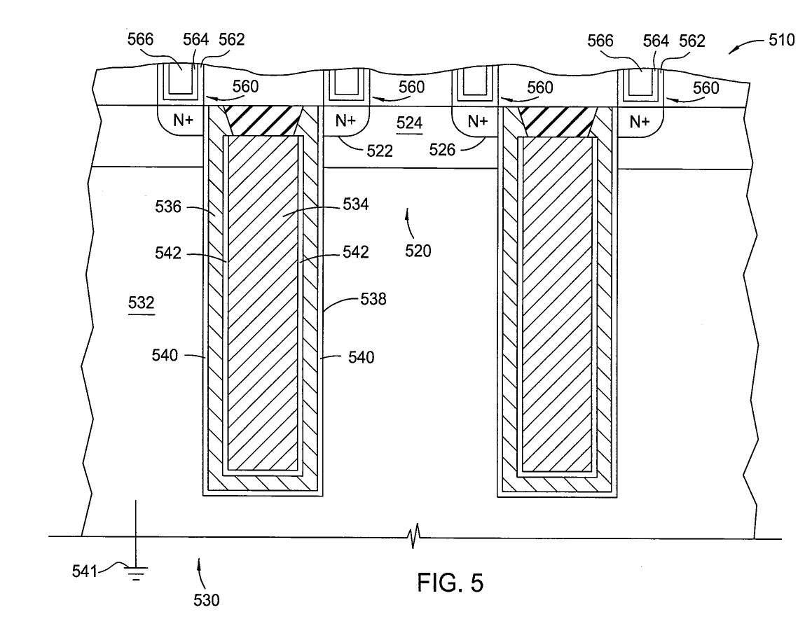

FIG. 5 is a cross sectional view of a conventional DRAM device having access transistor 520 positioned adjacent a top portion of trench capacitor 530. Access transistor 520 for DRAM device 510 is positioned adjacent a top portion of trench capacitor 530. Preferably, access transistor 520 contains a n-p-n transistor having source region 522, gate region 524, and drain region 526. Gate region 524 is a P⁻ doped silicon epi-layer disposed over the P⁺ substrate. Source region 522 of access transistor 520 is a N⁺ doped material disposed on a first side of gate region 524 and drain region 526 is a N⁺ doped material disposed on a second side of gate region 524, opposite source region 522.

Source and drain regions 522 and 524 may be connected to tungsten plug 560. Each tungsten plug 560 includes tungsten-containing material layer 562, tungsten nucleation layer 564, and bulk tungsten fill 566. The tungsten-containing material layer 562 may be a bi-layer stack comprising vapor deposited tungsten silicide followed by ALD deposited tungsten nitride. The tungsten-containing material layer 562 may be treated with one or more of the post-deposition plasma treatment and/or thermal anneal process described herein. While not shown, a passivation surface or layer may be formed within the upper portion of the tungsten-containing material layer 562 as described herein using the plasma treatment and/or thermal anneal process. Tungsten nucleation layer 564 may be formed by using a soak process and an ALD process or a soak process and a pulsed-CVD process. Tungsten bulk fill 566 may be deposited by using a post-soak process followed by a CVD process.

Trench capacitor 530 generally includes first electrode 532, second electrode 534 and dielectric material 536 disposed therebetween. The P⁺ substrate serves as first electrode 532 of trench capacitor 530 and is connected to ground connection 541. Trench 538 is formed in the P⁺ substrate and filled with a heavily doped N⁺ polysilicon that serves as second electrode 534 of trench capacitor 530. Dielectric material 536 is disposed between first electrode 532 (e.g., P⁺ substrate) and second electrode 534 (e.g., N⁺ polysilicon). Tungsten liner 562 may be a bi-layer stack comprising vapor deposited tungsten silicide followed by ALD deposited tungsten nitride.

Trench capacitor 530 also includes a first layer containing tungsten liner 540 disposed between dielectric material 536 and first electrode 532. Tungsten liner 540 may be a bi-layer stack comprising vapor deposited tungsten silicide followed by ALD deposited tungsten nitride. Preferably, a second layer containing tungsten liner 542 is disposed between dielectric material 536 and second electrode 534. Alternatively, tungsten liners 540 and 542 are a combination film, such as metallic tungsten/titanium nitride.

Any of the chemical vapor deposited or atomic layer deposited material used to form layers in the DRAM device may be treated post-deposition by one or more of the plasma treatment and/or thermal anneal process described herein. While not shown, a passivation surface or layer may be formed within the upper portion of any of the chemical vapor deposited or atomic layer deposited material as described herein using the plasma treatment and/or thermal anneal process.

Although the above-described DRAM device utilizes an n-p-n transistor, a P⁺ substrate as a first electrode, and an N⁺ polysilicon as a second electrode of the capacitor, other transistor designs and electrode materials are contemplated by the present invention to form DRAM devices. Additionally, other devices, such as crown capacitors for example, are contemplated by the present invention.

In one embodiment, a method is provided for forming a structure including depositing a polysilicon layer on a silicon substrate surface, depositing a first metal layer on the polysilicon layer, depositing a tantalum nitride layer on the first metal layer, treating a deposited tantalum nitride layer with a thermal anneal, a plasma treatment, or both, depositing a second metal layer on the treated tantalum nitride layer, depositing a patterned hard mark layer on the metal layer, selectively etching the second metal layer, the tantalum nitride layer, the first metal layer, and the polysilicon layer to expose vertical portions thereof, and selectively oxidizing the vertical portions of the polysilicon material and silicon substrate surface.

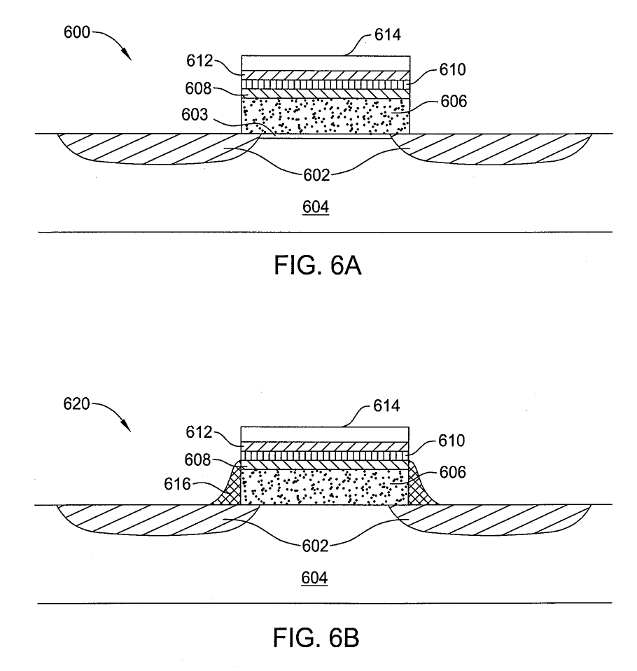

FIG. 6A illustrates a typical gate transistor structure 600. Doped silicide regions 602 are disposed within a polysilicon domain 604 of the substrate. The doped silicide regions 602 form source and drain regions for the transistor. Over the doped silicide regions 602, multiple layers of silicon oxide 603, polysilicon 606, gate barrier material 608, such as titanium, titanium nitride, or tungsten silicon nitride, barrier material 610, such as titanium nitride, tungsten nitride, and tantalum nitride, metal contacts 612, such as tungsten, and protective or hard mask material 614, such as silicon nitride may be deposited. Additionally, and not shown, metal contacts may be deposited directly atop the doped silicide regions, with or without barrier or nucleation layers between.

Selective oxidation oxidizes only the polysilicon and gate oxide layers, along with other silicon containing areas of the substrate, without oxidizing the metal or other layers. The gate barrier material 608, such as titanium, titanium nitride, or tungsten silicon nitride, barrier material 610, such as titanium nitride, tungsten nitride, and tantalum nitride, metal contacts 612, such as tungsten, may be deposited by atomic layer deposition and gate barrier material 608, barrier material 610, and metal contacts 612 may each be treated with one or more of the post-deposition plasma treatment and/or thermal anneal process described herein. While not shown, a passivation surface or layer may be formed within the upper portion of any of the gate barrier material 608, barrier material 610, and metal contacts 612 as described herein using the plasma treatment and/or thermal anneal process.

The selective oxidation process may be performed as follows. The chamber is ramped-up to a pressure from about 150 Torr to about 800 Torr, such as from about 250 Torr to 600 Torr, for example, as 450 Torr, and a temperature greater than about 700° C., such as from about 800° C. to about 1000° C., for example, about 950° C.

A hydrogen containing gas may be fed to the process chamber before or after ramping-up temperature and pressure. Although hydrogen (H₂) gas is preferred, another gas capable of producing water vapor when oxidized, such as ammonia (NH₃) may be used. When the desired flow rate of hydrogen containing gas is reached, and operating conditions established, an oxygen containing gas is fed into the process chamber to create a gas mixture. Although oxygen (O₂) gas is preferred, other oxidizing gases, such as nitrous oxide (N₂O) may be used. The hydrogen containing gas and the oxygen containing gas react, generating in-situ steam, which in turn drives the selective oxidation reaction on the substrate.

It has been found that a mixture of hydrogen gas (H₂) and oxygen gas (O₂) of greater than about 65% hydrogen creates the most advantageous reaction conditions. A hydrogen rich gas mixture generally results in acceptable oxidation rate and high selectivity. Favorable results have been obtained with a mixture of about 65% to about 95% hydrogen in oxygen, especially about 75% to about 90%, such as about 85% hydrogen in oxygen.

The reaction is allowed to proceed a set amount of time. A thin film of oxide growth on the silicon containing materials of the substrate is desired. At these process conditions, a duration of about 1 to about 5 minutes is sufficient to produce a new oxide layer 20 to 50 Angstroms thick. When the end point is reached, temperature may be ramped down and the reaction chamber may be pumped out and non-reactive gas charged. The chamber may be purged briefly to ensure no potentially reactive gases remain to degrade the substrate, and then the substrate is removed from the chamber for further processing.

FIG. 6B illustrates a device structure 620 after selective oxidation has been performed. Oxide layers 616 have grown adjacent to silicon containing layers of the structure. With the process of the present invention, oxidation selectivities of polysilicon and silicon dioxide relative to tungsten metal up to 99.6% have been obtained. The oxidation process may be used to selectively oxidize many silicon containing materials on a substrate, including, but are not limited to, polysilicon (or polycrystalline silicon), doped silicon, microcrystalline silicon, doped microcrystalline silicon, amorphous silicon, doped amorphous silicon, generic silicon, doped or undoped, not fitting any of the former labels, partially oxidized silicon materials substantially comprising silicon dioxide (SiO₂), and combinations thereof. Likewise, many popular metal conductors and barrier or protective layers may be safely exposed to this process. Metal layer compositions which will not be oxidized under such conditions include, but are not limited to, aluminum (Al), copper (Cu), tungsten (W), tungsten nitride (WN), titanium (Ti), titanium nitride (TiN), tantalum (Ta), tantalum nitride (TaN), tantalum carbonitride (TaCN), and combinations thereof.

A suitable selective oxidation process is disclosed in co-pending U.S. patent application Ser. No. 11/860,161, filed on Sep. 24, 2007, entitled “Method Of Improving Oxide Growth Rate Of Selective Oxidation Processes”, which is incorporate herein to the extent not inconsistent with the claim aspects and detail description herein.

In one example of the above process, a substrate having a gate barrier material 608, such as titanium nitride or tantalum nitride, formed thereon, such as by an ALD process, is transferred to a DPN chamber for the plasma treatment post-deposition process as described herein, transferred to the RTP anneal chamber for a thermal anneal process as described herein, and following additional layer deposition as necessary, which may be performed on the same tool or in the same chamber as appropriate, transferred to the same or different DPN chamber for the selective oxidation process as described herein. The barrier material 610 and metal contacts 612 may also be plasma and/or thermally treated as described herein prior to the selective oxidation process. The plasma treatment process, the thermal anneal process, the selective oxidation process, and optionally one or more layer deposition processes may be performed on the same tool, such as shown in FIG. 1.

In one embodiment, a method is provided for forming a structure including depositing a high k dielectric material on a silicon substrate surface, depositing a tantalum nitride layer on high k dielectric material, treating a deposited tantalum nitride layer with a thermal anneal, a plasma, anneal, or both, depositing a polysilicon layer on the treated tantalum nitride layer, depositing a patterned hard mark layer on the metal layer, selectively etching the polysilicon layer, the tantalum nitride layer, the high k dielectric material to expose vertical portions thereof, and selectively oxidizing the vertical portions of the polysilicon material and silicon substrate surface.

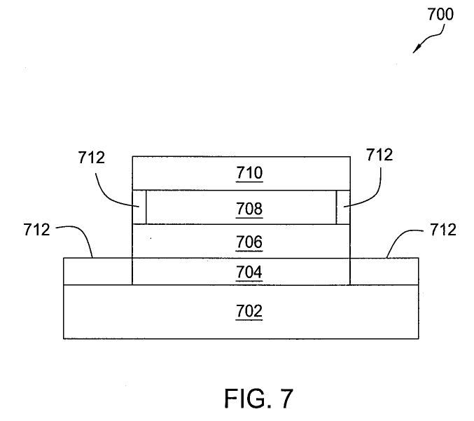

FIG. 7 illustrates a typical logic structure 700 after selective oxidation has been performed. A high K dielectric material 704, such as hafnium oxide, aluminum oxide, hafnium silicate among others, is disposed within a silicon domain 702 of the substrate. Over the high K dielectric material 704, multiple layers of barrier material 706, such as titanium, titanium nitride, or tungsten silicon nitride, polysilicon 708, and protective or hard mask material 710, such as silicon nitride may be deposited. The barrier material 706 may be a suitable barrier material including, but not limited to titanium, titanium nitride, or tungsten silicon nitride, which may be deposited by atomic layer deposition and each may be treated with one or more of the post-deposition plasma treatment and/or thermal anneal process described herein. While not shown, a passivation surface or layer may be formed within the upper portion of the barrier material 706 as described herein using the plasma treatment and/or thermal anneal process.

Oxide layers 712 have grown adjacent to silicon containing layers of the structure, such as on the vertical portions of the exposed polysilicon material 708.

### DEFINITIONS

“Substrate surface” or “substrate,” as used herein, refers to any substrate or material surface formed on a substrate upon which film processing is performed during a fabrication process. For example, a substrate surface on which processing may be performed include materials such as monocrystalline, polycrystalline or amorphous silicon, strained silicon, silicon on insulator (SOI), doped silicon, silicon germanium, germanium, gallium arsenide, glass, sapphire, silicon oxide, silicon nitride, silicon oxynitride, and/or carbon doped silicon oxides, for example, BLACK DIAMOND® low-k dielectric, available from Applied Materials, Inc., located in Santa Clara, Calif. Substrates may have various dimensions, such as 200 mm or 300 mm diameter substrates, as well as, rectangular or square panes, such as maybe used for LCDs or solar panel processing. Unless otherwise noted, embodiments and examples described herein are preferably conducted on substrates with a 200 mm diameter or a 300 mm diameter, more preferably, a 300 mm diameter. Embodiments of the processes described herein may be used to deposit metallic tungsten, tungsten nitride, tungsten boride, tungsten boride nitride, tungsten silicide, tungsten silicide nitride, tungsten phosphide, derivatives thereof, alloys thereof, combinations thereof, or other tungsten-containing materials on many substrates and surfaces, especially, on barrier layers, layers, or conductive layers. Substrates on which embodiments of the invention may be useful include, but are not limited to semiconductor substrates, such as crystalline silicon (e.g., Si<100> or Si<111>), silicon oxide, strained silicon, silicon germanium, doped or undoped polysilicon, doped or undoped silicon substrates, and patterned or non-patterned substrates. Substrates may be exposed to a pretreatment process to polish, etch, reduce, oxidize, hydroxylate, anneal, and/or bake the substrate surface.

“Atomic layer deposition” or “cyclical deposition” as used herein refers to the sequential introduction of two or more reactive compounds to deposit a layer of material on a substrate surface. The two, three or more reactive compounds may alternatively be introduced into a reaction zone of a processing chamber. Usually, each reactive compound is separated by a time delay to allow each compound to adhere and/or react on the substrate surface. In one aspect, a first precursor or compound A is pulsed into the reaction zone followed by a first time delay. Next, a second precursor or compound B is pulsed into the reaction zone followed by a second delay. During each time delay a purge gas, such as argon or nitrogen, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds.

In alternative embodiments, the purge gas may also be a reducing agent, such as hydrogen, diborane, or silane. The reactive compounds are alternatively pulsed until a desired film or film thickness is formed on the substrate surface. In either scenario, the ALD process of pulsing compound A, purge gas, pulsing compound B and purge gas is an ALD cycle. A cycle can start with either compound A or compound B and continue the respective order of the cycle until achieving a film with the desired thickness. In another embodiment, a first precursor containing compound A, a second precursor containing compound B, and a third precursor containing compound C are each separately and alternatively pulsed into the processing chamber. Alternatively, a first precursor containing compound A and a second precursor containing compound B are each separately and alternatively pulsed into the processing chamber while, and a third precursor containing compound C is continuously flowed into the processing chamber. Alternatively, a pulse of a first precursor may overlap in time with a pulse of a second precursor while a pulse of a third precursor does not overlap in time with either pulse of the first and second precursors.

A “pulse/dose” as used herein is intended to refer to a quantity of a particular compound that is intermittently or non-continuously introduced into a reaction zone of a processing chamber. The quantity of a particular compound within each pulse may vary over time, depending on the duration of the pulse. A particular compound may include a single compound or a combination of two or more compounds. The durations for each pulse/dose are variable and may be adjusted to accommodate, for example, the volume capacity of the processing chamber as well as the capabilities of a vacuum system coupled thereto. Additionally, the dose time of a compound may vary according to the flow rate of the compound, the pressure of the compound, the temperature of the compound, the type of dosing valve, the type of control system employed, as well as the ability of the compound to adsorb onto the substrate surface. Dose times may also vary based upon the type of layer being formed and the geometry of the device being formed. Typically, the duration for each pulse/dose or “dose time” is typically about 1.0 second or less. However, a dose time can range from microseconds to milliseconds to seconds, and even to minutes. In general, a dose time should be long enough to provide a volume of compound sufficient to adsorb or chemisorb onto the entire surface of the substrate and form a layer of the compound thereon.

While the foregoing is directed to embodiments of the present invention, other and further embodiments of the invention may be devised without departing from the basic scope thereof, and the scope thereof is determined by the claims that follow.

What is claimed is:

1. A method of processing a substrate, comprising;
depositing a metal-containing layer using an atomic layer deposition technique;
exposing the metal-containing layer to a plasma treatment process at a temperature of less than about 200° C.; and
exposing the metal-containing layer to a thermal anneal process at a temperature of about 600° C. or greater.

2. The method of claim 1, wherein the depositing a metal-containing layer using atomic layer deposition and the exposing the metal-containing layer to a plasma treatment are performed in the same chamber.

3. The method of claim 2, wherein the depositing a metal-containing layer using atomic layer deposition, the exposing the metal-containing layer to a plasma treatment are performed in the same chamber, and the exposing the metal-containing layer to a thermal anneal process are performed in situ on the same processing tool.

4. The method of claim 1, wherein the exposing the metal-containing layer to a plasma treatment and exposing the metal-containing layer to a thermal anneal process are performed on the same processing tool.

5. The method of claim 1, wherein the plasma treatment process is performed with a nitrogen gas.

6. The method of claim 5, wherein the plasma treatment process is performed at an RF power from about 500 W to about 2100 W and a temperature from about 20° C. to less than about 200° C.

7. The method of claim 1, wherein the thermal anneal process is performed with a nitrogen gas.

8. The method of claim 1, wherein the thermal anneal process is performed at a temperature from about 600° C. to about 1000° C.

9. The method of claim 1, wherein the thermal anneal process is performed at a temperature from about 900° C. to about 1000° C.

10. The method of claim 1, wherein the metal-containing layer is tantalum nitride;

11. A method of processing a substrate, comprising;
depositing a metal-containing layer using an atomic layer deposition technique;
exposing the metal-containing layer to a plasma treatment process comprising a nitrating gas;
forming a passivation layer on the metal-containing layer; and
exposing the metal-containing layer to a thermal anneal process.

12. The method of claim 11, wherein the nitrating gas is selected from the group consisting of activated-dinitrogen, ammonia, hydrazine, methylhydrazine, dimethylhydrazine, t-butylhydrazine, phenylhydrazine, azoisobutane, ethylazide, tert-butylamine, allylamine, derivatives thereof, and combinations thereof.

13. The method of claim 11, wherein the plasma treatment process is performed at a temperature of less than about 200° C. and the thermal anneal process is performed at a temperature of about 600° C. or greater.

14. The method of claim 11, wherein the exposing the metal-containing layer to a plasma treatment process comprising a nitrating gas, the forming a passivation layer on the meta-containing layer, and the exposing the metal-containing layer to a thermal anneal process are all performed in situ.

15. A method for forming a structure, comprising;
positioning a substrate in a processing chamber, and the substrate comprising a silicon substrate surface;
depositing a polysilicon layer on a silicon substrate surface;
depositing a first metal layer on the polysilicon layer;
depositing a tantalum nitride layer on the first metal layer;
treating a deposited tantalum nitride layer with a thermal anneal, a plasma, anneal, or both;
depositing a second metal layer on the treated tantalum nitride layer;
depositing a patterned hard mark layer on the metal layer;
selectively etching the second metal layer, the tantalum nitride layer, the first metal layer, and the polysilicon layer to expose vertical portions of the polysilicon layer; and
selectively oxidizing the silicon substrate surface and the vertical portions of the polysilicon material.

16. The method of claim 15, wherein the exposing the tantalum nitride layer to a plasma treatment and exposing the tantalum nitride layer to a thermal anneal process are performed on the same processing tool.

17. The method of claim 16, wherein the thermal anneal process is performed with a nitrogen gas at a temperature from about 600° C. to about 1000° C.

18. The method of claim 17, wherein the plasma treatment process is performed with a nitrogen gas at an RF power from about 500 W to about 2100 W and a temperature from about 100° C. to about 150° C.

19. The method of claim 17, wherein the thermal anneal process is performed at a temperature from about 900° C. to about 1000° C.

20. The method of claim 15, wherein the selectively oxidizing process comprises:
introducing an amount of a hydrogen containing gas and an amount of an oxygen containing gas to the chamber to form a gas mixture, wherein the gas mixture comprises a hydrogen rich gas mixture;
pressurizing the chamber to a pressure greater than about 250 Torr;
heating the chamber to a processing temperature to cause the gas mixture to react inside the chamber; and
selectively oxidizing the exposed vertical portions of the polysiliocn layer.

21. A method for forming a structure, comprising;
positioning a substrate in a processing chamber, and the substrate comprising a silicon substrate surface;
depositing a high k dielectric material on a silicon substrate surface;
depositing a tantalum nitride layer on high k dielectric material;
treating a deposited tantalum nitride layer with a thermal anneal, a plasma, anneal, or both;
depositing a polysilicon layer on the treated tantalum nitride layer;
depositing a patterned hard mark layer on the polysilicon layer;
selectively etching the polysilicon layer, the tantalum nitride layer, the high k dielectric material to expose vertical portions thereof; and
selectively oxidizing the silicon substrate surface and the vertical portions of the polysilicon material.

22. The method of claim 21, wherein the exposing the tantalum nitride layer to a plasma treatment and exposing the tantalum nitride layer to a thermal anneal process are performed on the same processing tool.

23. The method of claim 22, wherein the thermal anneal process is performed with a nitrogen gas at a temperature from about 600° C. to about 1000° C.

24. The method of claim 23, wherein the plasma treatment process is performed with a nitrogen gas at an RF power from about 500 W to about 2100 W and a temperature from about 100° C. to about 150° C.

25. The method of claim 21, wherein the selectively oxidizing process comprises:
introducing an amount of a hydrogen containing gas and an amount of an oxygen containing gas to the chamber to form a gas mixture, wherein the gas mixture comprises a hydrogen rich gas mixture;
pressurizing the chamber to a pressure greater than about 250 Torr;
heating the chamber to a processing temperature to cause the gas mixture to react inside the chamber; and
selectively oxidizing the exposed polysilicon layer.
